(19) United States
(12) Patent Application Publication
(10) Pub. No.: US 2012/0306790 A1
(43) Pub. Date: Dec. 6, 2012

(54) FILM TYPE APPARATUS FOR PROVIDING HAPTIC FEEDBACK AND TOUCH SCREEN INCLUDING THE SAME

(75) Inventors: Ki-Uk KYUNG, Daejeon (KR); Jeong-Mook LIM, Daejeon (KR); Sang-Youn KIM, Seoul (KR); Sung-Ryul YUN, Incheon (KR); Hee-Sook SHIN, Daejeon (KR); Jun-Seok PARK, Daejeon (KR)

(73) Assignee: Electronics and Telecommunications Research Institute, Daejeon (KR)

(21) Appl. No.: 13/485,004

(22) Filed: May 31, 2012

(30) Foreign Application Priority Data
Jun. 2, 2011 (KR) 10-2011-0053466
May 24, 2012 (KR) 10-2012-0055620

(51) Int. Cl. G06F 3/041; H03K 17/98; H03K 17/975

(52) U.S. Cl. 345/173; 327/517

(57) ABSTRACT

A film type apparatus for providing haptic feedback and a touch screen including the same are provided. In the film type apparatus, a plurality of unit haptic feedback providing apparatuses are arranged in an array. Each of the unit haptic feedback providing apparatuses includes a lower electrode, a lower charge capacitive member disposed on the lower electrode, an upper charge capacitive member disposed apart from the lower charge capacitive member, a spacer disposed between the lower and upper charge capacitive members to separate the lower and upper charge capacitive members, an upper electrode disposed on the upper charge capacitive member, and a charge supply unit connected to the lower and upper electrodes to supply electric charge.

### CROSS-REFERENCE TO RELATED APPLICATION

This application claims the benefit under 35 U.S.C. §119(a) of Korean Patent Applications No. 10-2011-0053466, filed on Jun. 2, 2011, and 10-2012-0055620, filed on May 24, 2012, the entire disclosures of which are incorporated herein by references for all purposes.

### BACKGROUND

1. Field

The following description relates to an apparatus for providing haptic feedback, and more particularly, to a film type apparatus for providing haptic feedback and a touch screen including the same, which provides various haptic sensations, such as a click feeling, to a user that uses a touch interface.

2. Description of the Related Art

In many electronic devices, a touch interface is being provided at present. For example, portable electronic devices such as mobile phones, smart phones, tablet computers, laptop computers, personal digital assistants (PDAs), portable multimedia players (PMPs), digital cameras, and portable game machines, and fixed type electronic devices such as automated teller machines (ATMs), information retrieval apparatuses, and automated ticket machines, include a touch screen as a touch interface.

Haptic technology, which provides a haptic sense to a user for reinforcing the user's experience in operational connection with the touch interface, is recently attracting much attention. The haptic technology provides various haptic senses to a user when the user interacts with a digital object, and thus provides feedback that is obtained by merging a visual sense and a haptic sense. Electronic devices using the haptic technology can provide a more realistic touch interface compared to existing electronic devices.

A motor scheme has been known as an example of haptic technology that provides a haptic sense to a user. According to the motor scheme, a vibration motor is disposed under a touch panel and vibrates the entire touch panel when an input from a user is sensed, thereby providing feedback. The motor scheme presently has a variety of uses in mobile devices because a response time is fast, power consumption is low, and it is easy to control haptic output. However, since a vibration motor module has a relatively large size, there is difficulty in disposing the module, and a mobile device becomes thicker overall. Moreover, the motor scheme has a structure in which vibration is transferred to the entire electronic device including a touch interface, and thus, it is difficult to provide a localized haptic sense to only a position touched by a user.

As demand for ever thinner electronic devices increases, technology that uses a film type haptic module or a film type module for providing haptic feedback using electro-active polymer (EAP) has been proposed for overcoming the limitations of the motor scheme. The technology uses deformation of an EAP film that is induced when a voltage is applied thereto, but since it is generally difficult to obtain a sufficient output (displacement) with only the deformation of the EAP film, an additional device (mass) having a certain weight is used together. That is, the deformation of the EAP film is a mechanism that moves the additional device and thus enables a user to receive haptic feedback according to the movement of the additional device. As a result, in the film type haptic module using the EAP film, the weight or size of the additional device play an important role for obtaining a sufficient output. The EAP module facilitates the manufacturing of a film type with the characteristics of a polymer, and moreover enables the implementation of a haptic module that has low power consumption and a fast response time. On the other hand, due to the additional device that is used together with the EAP film, the structure of the film type haptic module becomes complicated, and it is not easy to realize sensory localization.

### SUMMARY

The following description relates to a film type apparatus for providing haptic feedback which has a small volume, a thin thickness, and a simple structure, and a touch screen including the same.

The following description also relates to a film type apparatus for providing haptic feedback which has a small volume and a thin thickness, and moreover outputs localized haptic feedback from only a position touched by a user, and a touch screen including the same.

The following description also relates to a film type apparatus for providing haptic feedback which is disposed under a touch screen and outputs localized haptic feedback irrespective of whether the touch screen is flexible, and a touch screen including the same.

In one general aspect, an apparatus for providing haptic feedback includes: a first electrode; a first charge capacitive member disposed on the first electrode; a second charge capacitive member disposed apart from the first charge capacitive member; a spacer disposed between the first and second charge capacitive members to separate the first and second charge capacitive members; a second electrode disposed on the second charge capacitive member; and a charge supply unit connected to the first and second electrodes to supply electric charges.

The spacer may be disposed along an edge of each of the first and second charge capacitive members to limit a void at a central portion.

The first and second charge capacitive members may be formed of a non-crystalline material having a porous sponge structure.

The non-crystalline material may be cellulose acetate.

The charge supply unit may supply one of electric charge having the same polarity and electric charges having opposite polarities to the first and second electrodes.

The charge supply unit may selectively supply electric charge having the same polarity and electric charges having opposite polarities to the first and second electrodes.

The first and second electrodes, the first and second charge capacitive members, and the spacer may be all formed of a transparent material.

The apparatus for providing haptic feedback may further include a first assisting member disposed on the second electrode and formed of a material having greater rigidity than the second charge capacitive member.

The apparatus for providing haptic feedback may further include a second assisting member disposed under the first electrode and formed of a material having greater rigidity than the first charge capacitive member.

The first and second electrodes, the first and second charge capacitive members, the spacer, and the first and second assisting members may be all formed of a transparent material.

The first charge capacitive member, the spacer, and the second assisting member may be formed of the same material.

The first charge capacitive member, the spacer, and the second assisting member may be formed as one body.

In another general aspect, a film type apparatus for providing haptic feedback includes: a plurality of haptic feedback providing modules arranged in an array; and a transparent module separating member disposed between adjacent haptic feedback providing modules to separate the plurality of haptic feedback providing modules, wherein each of the haptic feedback providing modules includes: a first transparent electrode; a first charge capacitive member disposed on the first electrode; a transparent spacer disposed along an upper edge of the first charge capacitive member to limit a void at a central portion; a second charge capacitive member disposed on the spacer to at least cover an upper side of the void; a second transparent electrode disposed on the second charge capacitive member; and a charge supply unit connected to the first and second electrodes to supply electric charges.

The first and second charge capacitive members may be formed of a non-crystalline material having a porous sponge structure.

The charge supply unit may supply electric charge having the same polarity and/or electric charges having opposite polarities to the first and second electrodes.

The film type apparatus may further include a first assisting member disposed on the second electrode and formed of a material having greater rigidity than the second charge capacitive member.

One of the first and second electrodes may be formed as one body over the plurality of haptic feedback providing modules.

In another general aspect, a touch screen includes: a flat display; the film type apparatus disposed on the flat display; and a transparent touch panel disposed on the film type apparatus.

The touch panel may be flexible.

In another general aspect, a touch screen includes: a flat display; a transparent touch panel disposed on the flat display; and the film type apparatus disposed on the touch panel.

Other features and aspects will be apparent from the following detailed description, the drawings, and the claims.

### BRIEF DESCRIPTION OF THE DRAWINGS

FIG. 1A is a perspective view schematically illustrating a configuration of an apparatus for providing haptic feedback according to a first embodiment of the present invention.

FIG. 1B is a sectional view taken along line X-X′ of FIG. 1A.

FIG. 2A is a view illustrating deformation of the apparatus for providing haptic feedback according to the first embodiment when a lower charge capacitive member and an upper charge capacitive member are respectively charged with electric charge having different polarities.

FIG. 2B is a view illustrating deformation of the apparatus for providing haptic feedback according to the first embodiment when the lower charge capacitive member and the upper charge capacitive member are charged with electric charge having the same polarity.

FIG. 3A is a sectional view schematically illustrating a configuration of an apparatus for providing haptic feedback according to a second embodiment of the present invention.

FIG. 3B is a view illustrating deformation of the apparatus for providing haptic feedback according to the second embodiment when a lower charge capacitive member and an upper charge capacitive member are respectively charged with electric charge having different polarities.

FIG. 3C is a view illustrating deformation of the apparatus for providing haptic feedback according to the second embodiment when the lower charge capacitive member and the upper charge capacitive member are charged with electric charge having the same polarity.

FIG. 4A is a sectional view schematically illustrating a configuration of an apparatus for providing haptic feedback according to a third embodiment of the present invention.

FIG. 4B is a view illustrating deformation of the apparatus for providing haptic feedback according to the third embodiment when a lower charge capacitive member and an upper charge capacitive member are respectively charged with electric charge having different polarities.

FIG. 4C is a view illustrating deformation of the apparatus for providing haptic feedback according to the third embodiment when the lower charge capacitive member and the upper charge capacitive member are charged with electric charge having the same polarity.

FIG. 5A is a sectional view schematically illustrating a configuration of an apparatus for providing haptic feedback according to a fourth embodiment of the present invention when a voltage is not applied thereto.

FIG. 5B is a sectional view schematically illustrating a configuration of the apparatus for providing haptic feedback according to the fourth embodiment of the present invention when a voltage is applied thereto.

FIG. 6A is an exploded perspective view schematically illustrating a configuration of a film type apparatus for providing haptic feedback according to an embodiment of the present invention.

FIG. 6B is a sectional view taken along line Y-Y′ of FIG. 6A.

FIG. 7A is a view illustrating a schematic configuration of a touch screen according to an embodiment of the present invention.

FIG. 7B is a view illustrating a schematic configuration of a touch screen according to another embodiment of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

Hereinafter, embodiments of the present invention will be described in detail with reference to the accompanying drawings. Terms used herein are terms that have been selected in consideration of functions in embodiments, and the meanings of the terms may be altered according to the intent of a user or operator, or conventional practice. Therefore, the meanings of terms used in the below-described embodiments confirm to definitions when defined specifically in the specification, but when there is no detailed definition, the terms should be construed as meanings known to those skilled in the art. Furthermore, in the specification, it can be construed that when a first material layer is referred to as being formed ‘on’ or ‘under’ a second material layer, this includes a case where the first material layer is directly on or directly under the second material layer and, unless overtly excluded, a case (upper) where a third material layer is intervened between the second material layer and the first material layer.

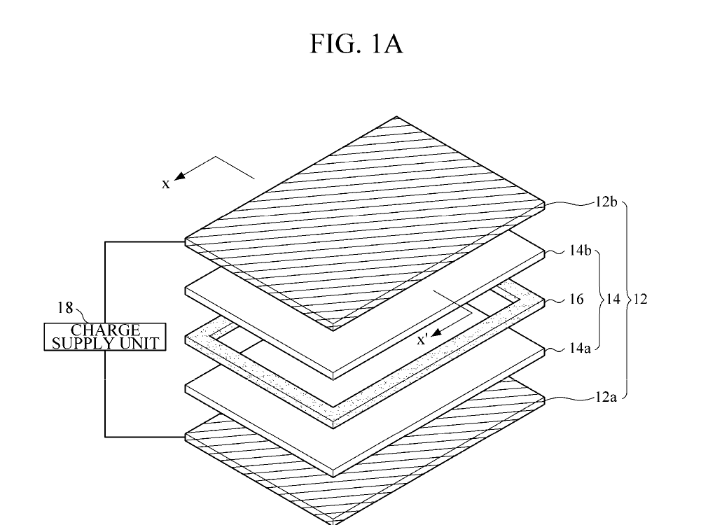

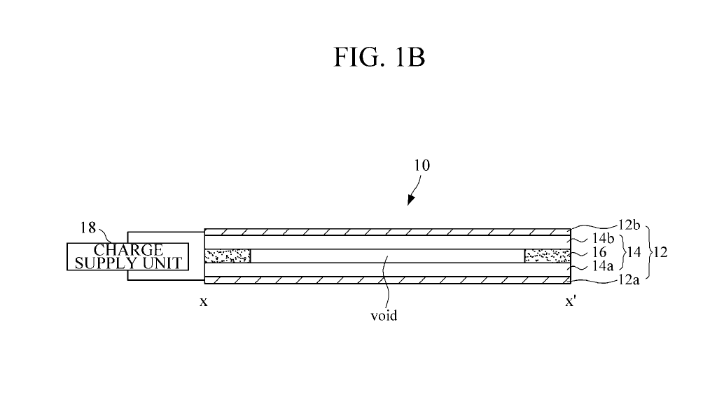

FIG. 1A is a perspective view schematically illustrating a configuration of an apparatus for providing haptic feedback according to a first embodiment of the present invention. FIG. 1B is a sectional view taken along line X-X′ of FIG. 1A. The apparatus for providing haptic feedback illustrated in FIGS. 1A and 1B may be a unit module that configures a film type apparatus for providing haptic feedback according to an embodiment of the present invention to be described below. The film type apparatus for providing haptic feedback is an apparatus that provides haptic feedback to a user when the film type apparatus is coupled to a touch type display (i.e., a touch screen) and the user interacts with an object output onto the touch screen with a finger, and its description will be made below in detail.

Referring to FIGS. 1A and 1B, a haptic feedback providing apparatus 10 includes a pair of electrodes 12, a pair of charge capacitive members 14, a spacer 16, and a charge supply unit 18.

In the below-described embodiment, it is assumed that a user touches an upper side of the haptic feedback providing apparatus 10, i.e., a position in a direction where an upper charge capacitive member 14b and an upper electrodes 12b are disposed. However, the restriction of directionality is merely for convenience of description, and an upper direction and a lower direction may be switched or the directionality may not be upward and downward but may be left and right according to an application of an electronic device including the haptic feedback providing apparatus 10.

The electrodes 12 receive electric charge from the charge supply unit 18 to transfer the electric charge to the charge capacitive members 14, and include a lower electrodes 12a and an upper electrodes 12b. The electrodes 12 are formed of a transparent conductive material, but are not limited thereto. For example, when the haptic feedback providing apparatus 10 is not coupled to a touch screen but to an opaque touch pad, the electrodes 12 may be formed of an opaque metal material. The transparent conductive material, for example, may be indium tin oxide (ITO), carbon nano-tube (CNT), grapheme or the like. The electrodes 12 may be formed to have a thin thickness of several tens μm or less.

The lower electrodes 12a and the upper electrodes 12b are connected to the charge supply unit 18. The charge supply unit 18 is an electronic device or an electronic circuit for supplying electric charge to the charge capacitive members 14 through the electrodes 12 connected thereto, and its detailed configuration is not limited. The charge supply unit 18 may supply electric charge having different polarities or electric charge having the same polarity to the lower charge capacitive member 14a and the upper charge capacitive member 14b. As an example of the former, the charge supply unit 18 may include a power source or a charging device. As an example of the latter, the charge supply unit 18 may include a charge pump or a charging device. Alternatively, according to embodiments, the charge supply unit 18 may include both the power source and the charging device, and selectively supply electric charge having different polarities and electric charge having the same polarity to the lower charge capacitive member 14a and the upper charge capacitive member 14b.

The charge capacitive member 14 acts as an electrified body that stores electric charge supplied through the electrodes 12. The charge capacitive member 14 includes the lower charge capacitive member 14a that is disposed on the lower electrodes 12a and stores electric charge supplied through the lower electrodes 12a, and the upper charge capacitive member 14b that is disposed under the upper electrodes 12a and stores electric charge supplied through the lower electrodes 12a. The lower charge capacitive member 14a and the upper charge capacitive member 14b may be charged with electric charge having different polarities or electric charge having the same polarity.

The haptic feedback providing apparatus 10 charges the pair of charge capacitive members 14 with electric charge having different polarities or the same polarity through the pair of electrodes 12, and provides haptic feedback to a user by using attraction or repulsion between the lower charge capacitive member 14a and the upper charge capacitive member 14b and/or deformation due to the attraction or the repulsion. To this end, the charge capacitive member 14 may be formed of a material such as a polymer with charging characteristics. The charge capacitive member 14 may be formed of a transparent material, but is not limited thereto. Also, the charge capacitive member 14 may be formed of an opaque material according to an application.

The charge capacitive member 14 may be effectively formed of a material that has a large charging capacity and a fast charging speed. As a charging capacity becomes larger, the level (intensity) of feedback increases. Furthermore, as a charging speed becomes higher, faster feedback is provided. For example, the charge capacitive member 14 may be formed of a non-crystalline material having a porous sponge structure. The non-crystalline material having the porous sponge structure is a material that has a good charging rate and is well electrified, and thus is suitable for a device using a transient electrostatic force. The non-crystalline material having the porous sponge structure may be, for example, cellulose acetate, but is not limited thereto.

According to an aspect of the present embodiment, the upper charge capacitive member 14b may at least have a certain level or higher of rigidity. When the upper charge capacitive member 14b has low rigidity, it is difficult to effectively transfer attraction or repulsion (or a feedback due thereto) between the lower charge capacitive member 14a and the upper charge capacitive member 14b to a user. That is, when the rigidity of the upper charge capacitive member 14b increases, an inertia change due to deformation increases, and thus, it is easy to transfer haptic feedback. On the other hand, when the rigidity of the upper and lower charge capacitive members 14a and 14b is lower than a force applied by a user, it is difficult to effectively transfer attraction or repulsion between the lower charge capacitive member 14a and the upper charge capacitive member 14b to the user's hand. For example, when the upper charge capacitive member 14b is formed of a polymer, the upper charge capacitive member 14b may have a thickness of about 200 μm or more for sufficiently rigidity.

Furthermore, the lower charge capacitive member 14a may also have a certain level or higher of rigidity according to an application. This is because when at least one of the lower and upper charge capacitive members 14a and 14b has low rigidity, the lower and upper charge capacitive members 14a and 14b may come into contact and short-circuit due to an attraction between the lower and upper charge capacitive members 14a and 14b.

The spacer 16 is disposed between the lower and upper charge capacitive members 14a and 14b to separate the lower and upper charge capacitive members 14a and 14b by a certain distance. The spacer 16 may be formed of an insulating material such as a polymer, and the kind of material is not limited. Furthermore, the height of the spacer 16 is not limited, but the spacer 16 needs to have a height that prevents the lower and upper charge capacitive members 14a and 14b from coming into contact and short-circuiting when an attraction is generated between the lower and upper charge capacitive members 14a and 14b and/or a user touches the haptic feedback providing apparatus 10 with a certain force. For example, the spacer 16 may have a height of about 100 μm or more.

According to embodiments, the spacer 16 may be disposed in a ring shape along an upper edge of the lower charge capacitive member 14a to limit a void at a central portion. When an attraction or a repulsion is generated between the lower and upper charge capacitive members 14a and 14b, the void allows respective deformations to occur in the charge capacitive member 14 and the electrodes 12. A change in height due to deformation of the charge capacitive member 14 and the electrodes 12 further reinforces a change in haptic feedback that is transferred to a user by an attraction or a repulsion.

Alternatively, the spacer 16 may not have a ring shape limiting a void but may have a plate shape (for example, a transparent glass). In this case, even when an attraction or a repulsion is generated between the lower and upper charge capacitive members 14a and 14b, the charge capacitive member 14 and the electrodes 12 are not deformed. Although the charge capacitive member 14 and the electrodes 12 are no deformed, haptic feedback that is different from preceding haptic feedback is transferred to a user by attraction or repulsion between the lower and upper charge capacitive members 14a and 14b.

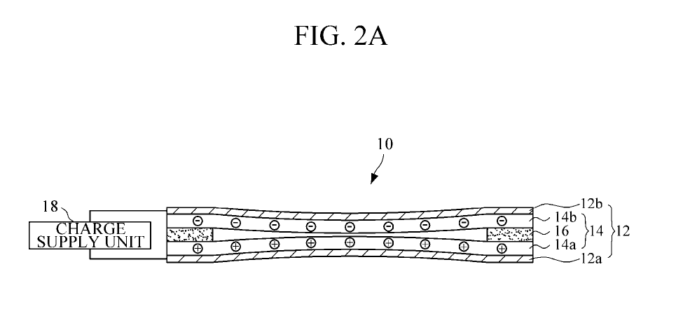

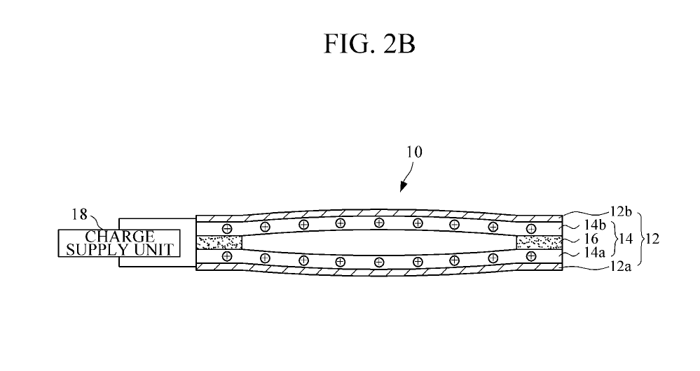

FIGS. 2A and 2B are views illustrating shapes in which the charge capacitive member 14 is charged with electric charge and deformed. FIG. 2A illustrates a case in which the lower and upper charge capacitive members 14a and 14b are charged with electric charge having different polarities, and FIG. 2B illustrates a case in which the lower and upper charge capacitive members 14a and 14b are charged with electric charge having the same polarity. It is obvious that the polarities of electric charge in the lower and upper charge capacitive members 14a and 14b in FIGS. 2A and 2B are just examples. Also, in FIGS. 2A and 2B, the lower and upper charge capacitive members 14a and 14b are illustrated as both being deformed, but only one of the lower and upper charge capacitive members 14a and 14b may be deformed according to an application (such as a case in which the haptic feedback apparatus 10 is attached and fixed to another device.).

Referring to FIGS. 2A and 2B, it can be seen that the lower and upper charge capacitive members 14a and 14b are charged with electric charge having different polarities or the same polarity, and an attraction or a repulsion is generated between the lower and upper charge capacitive members 14a and 14b. The attraction or repulsion between the lower and upper charge capacitive members 14a and 14b itself provides different haptic feedback to a user. Furthermore, when the charge capacitive member 14 and the electrodes 12 are deformed by the attraction or the repulsion, the deformation, i.e., the change in the physical height of the haptic feedback providing apparatus 10, can further reinforce the change in haptic feedback that is transferred to the user touching the haptic feedback providing apparatus 10.

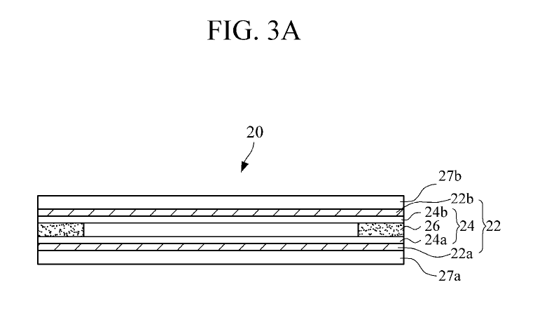

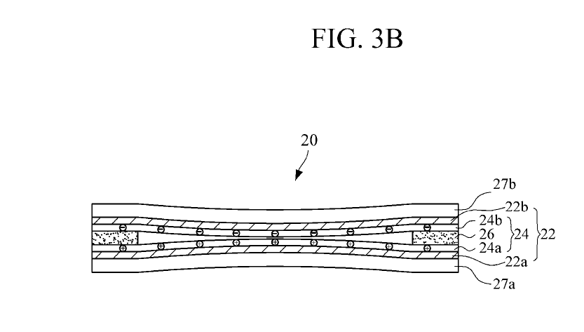

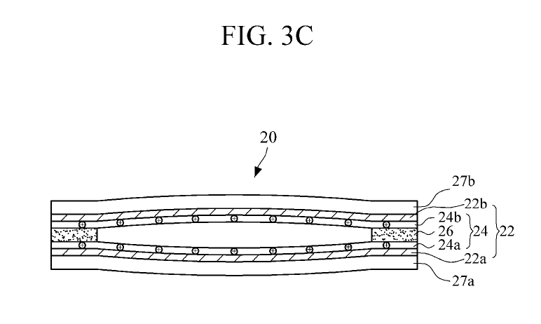

FIG. 3A is a sectional view schematically illustrating a configuration of an apparatus for providing haptic feedback according to a second embodiment of the present invention. The haptic feedback providing apparatus of FIG. 3A may be a unit module that configures a film type apparatus for providing haptic feedback according to an embodiment of the present invention to be described below.

Referring to FIG. 3A, a haptic feedback providing apparatus 20 includes a pair of electrodes 22, a pair of charge capacitive members 24, a spacer 26, a pair of assisting members 27, and a charge supply unit 28. There is a difference between the haptic feedback providing apparatus 20 and the haptic feedback providing apparatus 10 according to the first embodiment that has been described above with reference to FIGS. 1A and 1B in that the haptic feedback providing apparatus 20 of FIG. 3A further includes the pair of assisting members 27. The following description of the haptic feedback providing apparatus 20 of FIG. 3A will focus simply on the difference between the haptic feedback providing apparatus 20 and the haptic feedback providing apparatus 10 according to the first embodiment. For a detailed description of other aspects of the configuration of the haptic feedback providing apparatus 20, the reader may refer to the above description of the first embodiment.

The electrodes 22 receive electric charge from the charge supply unit 28 to transfer the electric charge to the charge capacitive members 24, and include a lower electrodes 22a and an upper electrodes 22b. The electrodes 22 may be formed of a transparent conductive material, but are not limited thereto. The charge supply unit 28 may be connected to the lower electrodes 22a and the upper electrodes 22b, and supply either electric charge having different polarities or electric charge having the same polarity to the lower charge capacitive member 24a and the upper charge capacitive member 24b. Alternatively, the charge supply unit 28 may selectively supply electric charge having different polarities and electric charge having the same polarity to the lower charge capacitive member 24a and the upper charge capacitive member 24b. The spacer 26 is disposed between the lower and upper charge capacitive members 24a and 24b to separate the lower and upper charge capacitive members 24a and 24b by a certain distance.

The charge capacitive member 24 acts as an electrified body that stores electric charge supplied through the electrodes 22. The charge capacitive member 24 includes the lower charge capacitive member 24a and the upper charge capacitive member 24b. The charge capacitive member 24 may be formed of a transparent polymer with charging characteristics, for example, cellulose acetate that has a porous sponge structure and is not crystalline.

According to the present embodiment, both the lower charge capacitive member 24a and the upper charge capacitive member 24b have a relatively thin thickness, for example, a thickness of 200 μm or less. A polymer having the thin thickness has low rigidity, and thus, it is difficult to effectively transfer feedback to a user. The pair of assisting members 27 compensate for the limitation of transfer, and include a lower assisting member 27a and an upper assisting member 27b. That is, the assisting member 27 enhances the intensity of the haptic feedback providing apparatus 20, thereby enabling a sufficient level of feedback to be transferred to a user. Therefore, the assisting member 27 may be formed of a rigid material having a certain level or higher of rigidity. The assisting member 27 may be formed of a transparent material according to an application, in which case the assisting member 27 may be formed of glass.

FIGS. 3B and 3C are views illustrating shapes in which the charge capacitive member 24 is charged with electric charge and deformed. FIG. 3B illustrates a case in which the lower and upper charge capacitive members 24a and 24b are charged with electric charge having different polarities, and FIG. 3C illustrates a case in which the lower and upper charge capacitive members 24a and 24b are charged with electric charge having the same polarity. It is obvious that the polarities of electric charge in the lower and upper charge capacitive members 24a and 24b in FIGS. 3B and 3C are just examples. Also, in FIGS. 3B and 3C, the lower and upper charge capacitive members 24a and 24b and the assisting member 27 are illustrated as both being deformed, but this is also just an example.

Referring to FIGS. 3B and 3C, it can be seen that the lower and upper charge capacitive members 24a and 24b are charged with electric charge having different polarities or the same polarity, and an attraction or a repulsion is generated between the lower and upper charge capacitive members 24a and 24b. As in the above-described first embodiment, the attraction or repulsion between the lower and upper charge capacitive members 24a and 24b itself provides different haptic feedback to a user. Furthermore, when the charge capacitive member 24, the assisting member 27, and the electrodes 22 are deformed by the attraction or the repulsion, the deformation, i.e., the change in the physical height of the haptic feedback providing apparatus 20, can further reinforce the change in haptic feedback that is transferred to the user touching the haptic feedback providing apparatus 20.

As seen with reference to FIGS. 3B and 3C, in the haptic feedback providing apparatus 20 according to the second embodiment, since the charge capacitive member 24 has a thin thickness, a degree in which the charge capacitive member 24 is bent by an electrostatic force (attraction or repulsion) between electric charges is greater than in the charge capacitive member 14 (see FIGS. 2A and 2B) according to the first embodiment. However, when the charge capacitive member 24 is thin compared to a force applied by a user, it is difficult to effectively transfer attraction or repulsion between the lower charge capacitive member 24a and the upper charge capacitive member 24b to the user. In this way, when the attraction or the repulsion is generated between the lower charge capacitive member 24a and the upper charge capacitive member 24b, the assisting member 27 increases the change in inertia, and thus increases feedback provided to the user.

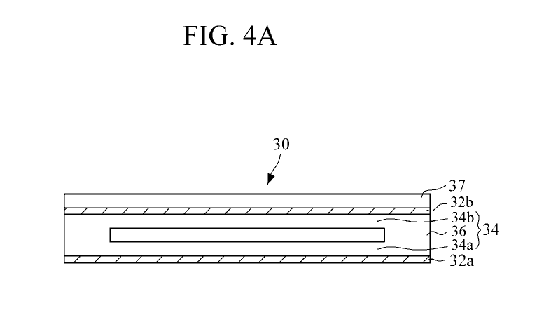

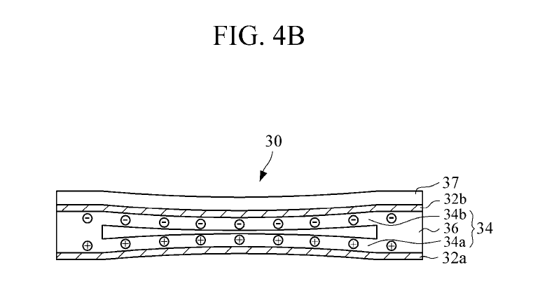

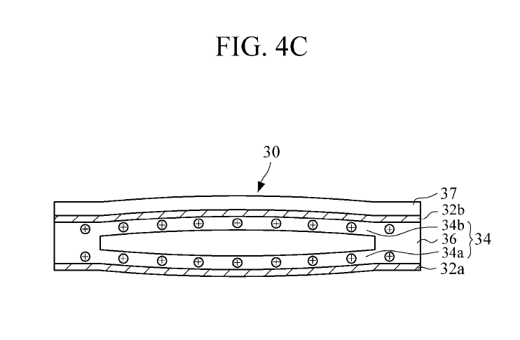

FIG. 4A is a sectional view schematically illustrating a configuration of an apparatus for providing haptic feedback according to a third embodiment of the present invention. The haptic feedback providing apparatus of FIG. 4A may be a unit module that configures a film type apparatus for providing haptic feedback according to an embodiment of the present invention to be described below.

Referring to FIG. 4A, like the haptic feedback providing apparatus 20 of FIG. 3A, a haptic feedback providing apparatus 30 includes a pair of electrodes 32, a charge capacitive member 34, a spacer 36, an assisting member 37, and a charge supply unit 38. The following description of the haptic feedback providing apparatus 30 of FIG. 4 will focus simply on the differences between the haptic feedback providing apparatus 30 and the haptic feedback providing apparatuses 10 and 20. For a detailed description of other aspects of the configuration of the haptic feedback providing apparatus 30, the reader may refer to the above description of the first and second embodiments.

There is a difference between the haptic feedback providing apparatus 30 according to the present embodiment and the haptic feedback providing apparatuses 10 and 20 of the first and second embodiments in that the charge capacitive member 34 and the spacer 36 are formed of the same material and formed as one body. The charge capacitive member 34 and the spacer 36 have a certain thickness, and may be formed of a polymer in which a void is formed. Alternatively, a transparent glass plate may be disposed at an internal portion (a portion in which the void of FIG. 4A is formed.). In this case, a portion of the polymer that is disposed at a lower portion of the void and is adjacent to a lower electrode 32a corresponds to a lower charge capacitive member 34a, and a portion of the polymer that is disposed at an upper portion of the void and is adjacent to an upper electrode 32b corresponds to an upper charge capacitive member 34b. Furthermore, a portion that surrounds the void in the side direction of the void corresponds to the spacer 36.

There is a difference between the haptic feedback providing apparatus 30 according to the present embodiment and the haptic feedback providing apparatuses 20 of the second embodiment in that an assisting member is not disposed under the lower electrode 32a because the assisting member 37 is disposed only on the upper electrode 32b. As described above, the assisting member 37 has a certain level of rigidity and thus efficiently transfers the change in haptic feedback to a user, and therefore, the assisting member 37 may not be disposed at a position that is not touched by a user. In addition, as in the first embodiment, when the lower charge capacitive member 34a is sufficiently thick or the haptic feedback providing apparatus 30 is disposed to be attached to an upper side of another device, an assisting member may not be disposed under the lower electrode 32a.

The electrodes 32 receive electric charge from the charge supply unit 38 to transfer the electric charge to the charge capacitive member 34, and include the lower electrode 32a and the upper electrode 32b. The charge supply unit 38 may be connected to the lower electrode 32a and the upper electrode 32b and supply either electric charge having different polarities or electric charge having the same polarity to the lower charge capacitive member 34a and the upper charge capacitive member 34b. Alternatively, the charge supply unit 38 may selectively supply electric charge having different polarities and electric charge having the same polarity to the lower charge capacitive member 34a and the upper charge capacitive member 34b.

FIGS. 4B and 4C are views illustrating shapes in which the charge capacitive member 34 is charged with electric charge and deformed. FIG. 4B illustrates a case in which the lower and upper charge capacitive members 34a and 34b are charged with electric charge having different polarities, and FIG. 4C illustrates a case in which the lower and upper charge capacitive members 34a and 34b are charged with electric charge having the same polarity. It is obvious that the polarities of electric charge in the lower and upper charge capacitive members 34a and 34b in FIGS. 4B and 4C are just examples. Also, in FIGS. 4B and 4C, the lower and upper charge capacitive members 24a and 24b and the assisting member 27 are illustrated as both being deformed, but this is also just an example.

Referring to FIGS. 4B and 4C, it can be seen that the lower and upper charge capacitive members 34a and 34b are charged with electric charge having different polarities or the same polarity, and an attraction or a repulsion is generated between the lower and upper charge capacitive members 34a and 34b. Like in the above-described first and second embodiments, the attraction or repulsion between the lower and upper charge capacitive members 34a and 34b itself provides different haptic feedback to a user. Furthermore, when the charge capacitive member 34, the assisting member 37, and the electrode 32 are deformed by the attraction or the repulsion, the deformation, i.e., the change in the physical height of the haptic feedback providing apparatus 30 can further reinforce the change in haptic feedback that is transferred to the user touching the haptic feedback providing apparatus 30. Also, when the attraction or the repulsion is generated between the lower charge capacitive member 34a and the upper charge capacitive member 34b, the assisting member 37 increases the change in inertia, and thus increases feedback provided to the user.

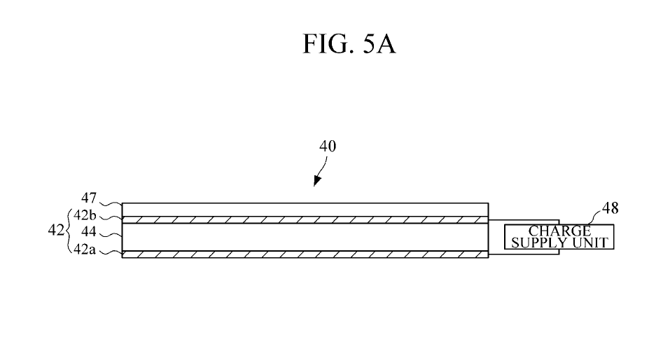

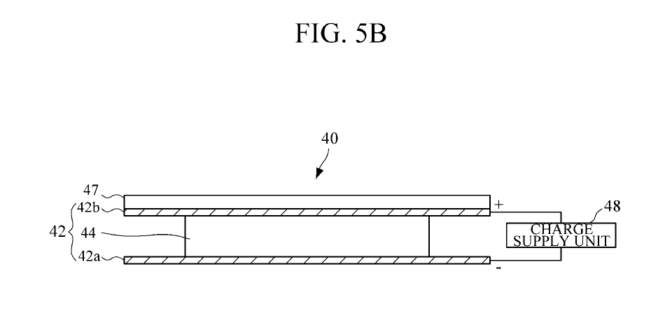

FIG. 5A is a sectional view schematically illustrating a configuration of an apparatus for providing haptic feedback according to a fourth embodiment of the present invention. The haptic feedback providing apparatus of FIG. 5A may be a unit module that configures a film type apparatus for providing haptic feedback according to an embodiment of the present invention to be described below.

Referring to FIG. 5A, a haptic feedback providing apparatus 40 includes a pair of electrodes 42, an EAP layer 44, an assisting member 47, and a charge supply unit 48. The haptic feedback providing apparatus 40 according to the present embodiment resembles the above-described embodiments in that a polymer is disposed between the pair of electrodes 42. However, there is a difference between the present embodiment and the above-described embodiments in that a polymer is used as an electrified body in the above-described embodiments, but the haptic feedback providing apparatus 40 according to the present embodiment uses properties in which an EAP is deformed by an electric field. The following description of the haptic feedback providing apparatus 40 of FIG. 5A will focus simply on the differences between the haptic feedback providing apparatus 40 and the haptic feedback providing apparatuses 10, 20 and 30. For a detailed description of other aspects of the configuration of the haptic feedback providing apparatus 40, the reader may refer to the above description of the first through third embodiments.

The pair of electrodes 42 generate an electric field with a voltage applied from the charge supply unit 48, and include a lower electrode 42a and an upper electrode 42b. The lower electrode 42a and the upper electrode 42b are connected to the charge supply unit 48. The charge supply unit 48 may include a charging device or a power source that supplies electric charge having different polarities. Furthermore, the assisting member 47 having a certain level of rigidity is disposed on the upper electrode 42b and efficiently transfers the change in haptic feedback due to the deformation of the EAP layer 44 to a user.

An EAP forming the EAP layer 44 is a material that is deformed by an applied electric field. That is, when an electric field is generated by an electric potential difference between both ends of the EAP, the internal structure of the EAP is deformed, and thus the shape of the EAP is changed. At this point, the entire volume of the EAP is not changed. For example, when voltages are applied to both ends of the EAP, the EAP increases in length and simultaneously decreases in thickness, or the EAP decreases in length and simultaneously increases in thickness. The thickness change may be transferred to a user's hand touching the haptic feedback providing apparatus 40 so that the user senses the change in haptic feedback. FIG. 5B is a view illustrating an example of a shape in which the EAP layer 44 is deformed by voltages applied to the lower and upper electrodes 42 of the haptic feedback providing apparatus 40 of FIG. 5A, and it can be seen that the thickness of the EAP layer 44 has increased by an electric field.

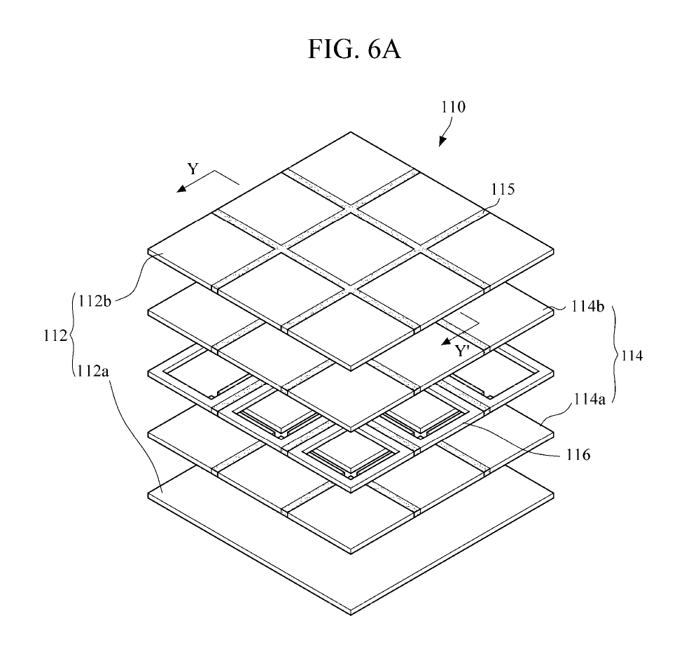

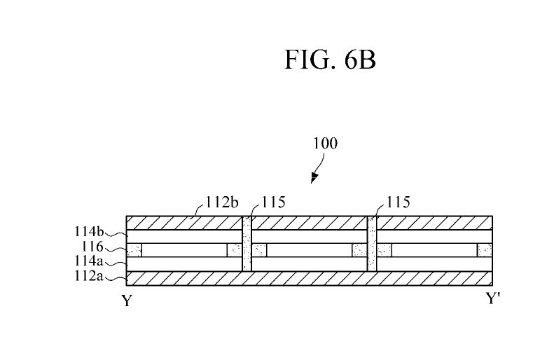

FIG. 6A is an exploded perspective view schematically illustrating a configuration of a film type apparatus for providing haptic feedback according to an embodiment of the present invention. FIG. 6B is a sectional view taken along line Y-Y′ of FIG. 6A. The film type haptic feedback providing apparatus 110 of FIGS. 6A and 6B may be an apparatus in which unit modules of the above-described haptic feedback providing apparatus 10 of the first embodiment are arranged in a 3×3 array, and is merely an example. In FIGS. 6A and 6B, for convenience of illustration, the charge supply unit 18 of the haptic feedback providing apparatus 10 is not illustrated. According to FIGS. 6A and 6B, the configuration of a film type haptic feedback providing apparatus including the haptic feedback providing apparatuses 20, 30 and 40 of the second to fourth embodiments as unit modules may be provided, and thus, its detailed illustration and description are not provided.

Referring to FIGS. 6A and 6B, the film type haptic feedback providing apparatus 110 includes a lower electrode 112a, a lower charge capacitive member 114a, a spacer 116, an upper charge capacitive member 114b, and an upper electrode 112b. In the present embodiment, the lower electrode 112a has a sheet-like form overall, but the upper electrode 112b is formed in pieces corresponding to each unit module. This is merely one example implementation of a structure that supplies electric charge for an attraction or a repulsion to act between the lower and upper charge capacitive members 114a and 114b in modular units. Therefore, the present embodiment is not limited thereto, and the shape of the lower electrode 112a may be opposite to that of the upper electrode 112b or formed in modular pieces. Alternatively, the lower electrode 112a may have a shape in which a plurality of conductive lines extending in a first direction are disposed, and the upper electrode 112b may have a shape in which a plurality of conductive lines extending in a second direction perpendicularly intersecting the first direction are disposed.

Furthermore, the film type haptic feedback providing apparatus 110 may further include a module separating member 115. The module separating member 115 physically isolates a plurality of unit modules configuring the film type haptic feedback providing apparatus 110, i.e., the haptic feedback providing apparatuses 10 (see FIG. 1). The isolating structure for each module prevents a physical force (electrostatic attraction or repulsion) that is generated in a module and/or deformation due to the physical force from being transferred to an adjacent module. Accordingly, the film type haptic feedback providing apparatus 110 can more effectively localize haptic feedback.

To this end, the module separating member 115 is formed of a material with insulating characteristic at least. Furthermore, the module separating member 115 is disposed to at least isolate adjacent charge capacitive members 114. For example, as illustrated in FIG. 6B, the module separating member 115 may have a height adjacent to the lower charge capacitive member 114a, spacer 116, upper charge capacitive member 114b, and upper electrode 112b, and thus may be disposed between adjacent modules. The module separating member 115 may be formed of a transparent material. For example, the module separating member 115 may be formed of glass or a transparent polymer.

The above-described film type haptic feedback providing apparatus according to an embodiment of the present invention may be used as an element of a touch screen that provides haptic feedback to a user. The film type haptic feedback providing apparatus may be the apparatus of FIGS. 6A and 6B, but is not limited thereto. For example, in the film type haptic feedback providing apparatus, a plurality of unit modules may be arranged not in a 3×3 array but in an M×N array (where M and N are integers equal to or more than two), and/or the unit module may not be the haptic feedback providing apparatus of the first embodiment but may be one of the haptic feedback providing apparatuses of the second to fourth embodiments.

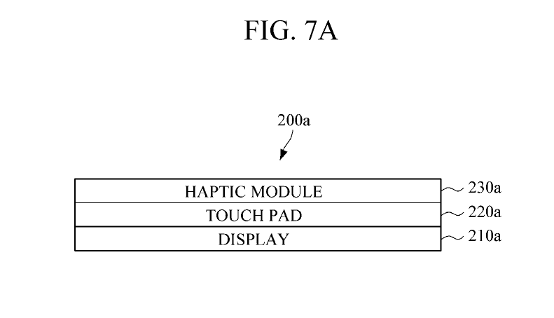

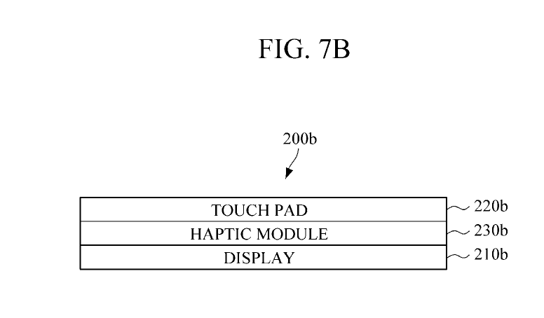

FIG. 7A is a view illustrating a schematic configuration of a touch screen according to an embodiment of the present invention. FIG. 7B is a view illustrating a schematic configuration of a touch screen according to another embodiment of the present invention. In FIGS. 7A and 7B, a plurality of modules configuring the touch screen are conceptually illustrated for showing that the film type haptic feedback providing apparatus may be used as an element of the touch screen. This is because a detailed implementation method is not limited.

Referring to FIGS. 7A and 7B, a touch screen 200a includes a flat display 210a, a film type haptic feedback providing apparatus 220a, and a touch panel 230a. And a touch screen 200b includes a flat display 210b, a film type haptic feedback providing apparatus 220b, and a touch panel 230b. Here, the film type haptic feedback providing apparatus 220 includes one of the haptic feedback providing apparatuses of the first to fourth embodiments as a unit module, and it is obvious to those skilled in the art that the film type haptic feedback providing apparatus 220 is formed of a transparent material so as to be used in the touch screens 200a and 200b. The touch screen 200a of FIG. 7A and the touch screen 200b of FIG. 7B have a difference in the disposition of their modules. For example, in the touch screen 200a of FIG. 7A, the touch panel 230a is disposed on the flat display 210a, and the film type haptic feedback providing apparatus 220a is disposed on the touch panel 230a. On the other hand, in the touch screen 200b of FIG. 7B, the film type haptic feedback providing apparatus 220b is disposed on the flat display 210b, and the touch panel 230b is disposed on the film type haptic feedback providing apparatus 220b. In the touch screen 200b, the touch panel 230b may have a flexible feature. This is for allowing localized deformation of the film type haptic feedback providing apparatus 220b to be efficiently transferred to a user as haptic feedback through the touch panel 230b.

The apparatus for providing haptic feedback according to the embodiments of the present invention uses attraction or repulsion between the pair of charge capacitive members that are disposed to face each other and/or deformation due to the attraction or the repulsion, and thus, has a small overall volume, a thin thickness, and a simple structure, and outputs localized haptic feedback from only a position touched by a user.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An apparatus for providing haptic feedback, comprising:
a first electrode;
a first charge capacitive member disposed on the first electrode;
a second charge capacitive member disposed apart from the first charge capacitive member;
a spacer disposed between the first and second charge capacitive members to separate the first and second charge capacitive members;
a second electrode disposed on the second charge capacitive member; and
a charge supply unit connected to the first and second electrodes to supply electric charges.

2. The apparatus of claim 1, wherein the spacer is disposed along an edge of each of the first and second charge capacitive members to limit a void at a central portion.

3. The apparatus of claim 1, wherein the first and second charge capacitive members are formed of a non-crystalline material having a porous sponge structure.

4. The apparatus of claim 3, wherein the non-crystalline material is cellulose acetate.

5. The apparatus of claim 1, wherein the charge supply unit supplies one of electric charge having the same polarity and electric charges having opposite polarities to the first and second electrodes.

6. The apparatus of claim 5, wherein the charge supply unit selectively supplies electric charge having the same polarity and electric charges having opposite polarities to the first and second electrodes.

7. The apparatus of claim 1, wherein the first and second electrodes, the first and second charge capacitive members, and the spacer are all formed of a transparent material.

8. The apparatus of claim 1, further comprising a first assisting member disposed on the second electrode and formed of a material having greater rigidity than the second charge capacitive member.

9. The apparatus of claim 8, further comprising a second assisting member disposed under the first electrode and formed of a material having greater rigidity than the first charge capacitive member.

10. The apparatus of claim 9, wherein the first and second electrodes, the first and second charge capacitive members, the spacer, and the first and second assisting members are all formed of a transparent material.

11. The apparatus of claim 1, wherein the first charge capacitive member, the spacer, and the second assisting member are formed of the same material.

12. The apparatus of claim 11, wherein the first charge capacitive member, the spacer, and the second assisting member are formed as one body.

13. A film type apparatus for providing haptic feedback, comprising:
a plurality of haptic feedback providing modules arranged in an array; and
a transparent module separating member disposed between adjacent haptic feedback providing modules to separate the plurality of haptic feedback providing modules,
wherein each of the haptic feedback providing modules comprises:
a first transparent electrode;
a first charge capacitive member disposed on the first electrode;
a transparent spacer disposed along an upper edge of the first charge capacitive member to limit a void at a central portion;
a second charge capacitive member disposed on the spacer to at least cover an upper side of the void;
is a second transparent electrode disposed on the second charge capacitive member; and
a charge supply unit connected to the first and second electrodes to supply electric charges.

14. The film type apparatus of claim 13, wherein the first and second charge capacitive members are formed of a non-crystalline material having a porous sponge structure.

15. The film type apparatus of claim 13, wherein the charge supply unit supplies electric charge having the same polarity and/or electric charges having opposite polarities to the first and second electrodes.

16. The film type apparatus of claim 13, further comprising a first assisting member disposed on the second electrode and formed of a material having greater rigidity than the second charge capacitive member.

17. The film type apparatus of claim 13, wherein one of the first and second electrodes is formed as one body over the plurality of haptic feedback providing modules.

18. A touch screen, comprising:
a flat display;
the film type apparatus of claim 13 disposed on the flat display; and
a transparent touch panel disposed on the film type apparatus.

19. The touch screen of claim 18, wherein the touch panel is flexible.

20. A touch screen, comprising:
a flat display;
a transparent touch panel disposed on the flat display; and
the film type apparatus of claim 13 disposed on the touch panel.
